(19) United States
(12) Patent Application Publication
(10) Pub. No.: US 2013/0137274 A1
(43) Pub. Date: May 30, 2013

(54) SUBSTRATE PROCESSING METHOD

(71) Applicant: HITACHI-KOKUSAI ELECTRIC INC., TOKYO (JP)

(72) Inventor: Hironori TAKAHASHI, Toyama-shi (JP)

(73) Assignee: HITACHI-KOKUSAI ELECTRIC INC., TOKYO (JP)

(21) Appl. No.: 13/684,599

(22) Filed: Nov. 26, 2012

Related U.S. Application Data
(63) Continuation of application No. 12/632,265, filed on Dec. 7, 2009.

(30) Foreign Application Priority Data
Dec. 9, 2008 (JP) 2008-313144
Dec. 3, 2009 (JP) 2009-275050

(51) Int. Cl. H01L 21/465

(52) U.S. Cl. CPC H01L 21/465
USPC 438/714

(57) ABSTRACT

There is provided a substrate processing method to suppress popping while increasing the throughput in a photoresist removing process. The substrate processing method comprises: loading a substrate, which is coated with photoresist into which a dopant is introduced, into a process chamber; heating the substrate; supplying a reaction gas to the process chamber, wherein the reaction gas contains at least oxygen and hydrogen components, and concentration of the hydrogen component ranges from 60% to 70%; and processing the substrate in a state where the reaction gas is excited into plasma. In the heating of the substrate, the substrate may be heated to 220° C. to 300° C. In the heating of the substrate, the substrate may be heated to 250° C. to 300° C.

### CROSS-REFERENCE TO RELATED PATENT APPLICATION

The present application is continuation application of U.S. patent application Ser. No. 12/632,265, filed on Dec. 7, 2009; which relates to and claims priority under 35 U.S.C. §119 of Japanese Patent Application No. 2008-313144, filed on Dec. 9, 2008 and Japanese Patent Application No. 2009-275050, filed on Dec. 3, 2009 in the Japanese Patent Office, the entire contents of which are hereby incorporated by reference.

### BACKGROUND OF THE INVENTION

1. Field of the Invention

The present invention relates to a substrate processing method for a semiconductor manufacturing apparatus (such as an ashing apparatus) configured to process a substrate, for example, in a semiconductor manufacturing process.

2. Description of the Prior Art

Patent Document 1 discloses an ashing apparatus including a reaction chamber, a unit configured to induce and maintain a high-frequency gas discharge state in the reaction chamber, and a chamber directly connected to the reaction chamber and including a built-in semiconductor substrate holding stage to hold a semiconductor substrate. In the disclosed ashing apparatus, only oxygen gas is introduced into the reaction chamber while exhausting the reaction chamber and the chamber connected to the reaction chamber, and the pressures of the reaction chamber and the chamber are kept in the range from 250 Pa to 650 Pa during an ashing process.

Patent Document 2 discloses a semiconductor device manufacturing method including a process of removing photoresist from a substrate. The removing process includes supplying at least oxygen gas at 250 sccm or higher rate and hydrogen gas at 750 sccm or higher rate to a reaction vessel so as to obtain an hydrogen/oxygen ratio of 3 or higher, plasma-processing the oxygen gas and the hydrogen gas in the reaction vessel, and performing an ashing process on substrates accommodated in process chambers installed sequentially in the reaction vessel.

For example, according to a known technique, when forming a gate, a source, and a drain of a transistor in a semiconductor manufacturing process, an ashing process or an ion (impurity) implanting process is performed by using photoresist as a mask, the photoresist is removed after the ion implanting process, and then a predetermined process is performed to form a transistor.

[Patent Document 1]
Japanese Unexamined Patent Application Publication No. 2008-91750

[Patent Document 2]
Japanese Unexamined Patent Application Publication No. 2009-164365

In an ion implanting process, ions are implanted at a high concentration to increase the impurity concentration and thus to decrease the resistance of a source or drain. As described above, since ions are implanted in a state where photoresist is applied to a substrate, the ions are implanted into the photoresist as well as a source or a drain.

At this time, due to the implanted ions, the surface layer of the photoresist is changed in quality and hardened.

If an ashing process is performed in this state, a layer (bulk layer) of the photoresist located under the hardened surface layer (hardened layer) of the photoresist may become flowable, and bubbles included in the photoresist may be heated and enlarged to tear the hardened surface layer and spout out from the photoresist. This is so-called “popping phenomenon.”

If such a popping phenomenon occurs, abnormally oxidized organic components, and oxides of dopants such as phosphorus (P), arsenic (As), and boron (B) implanted into photoresist through an ion implanting process may not be removed by an ashing process, and thus undesirable residues may be formed on a substrate. In addition, broken photoresist may be attached to the wall of a reaction chamber, and the attached photoresist may generate particles. Due to such particles, a substrate may be contaminated.

As a way of preventing such a popping phenomenon, a conventional ashing process can be performed for a long time to remove photoresist while preventing a popping phenomenon; however, in this case, throughput is low.

### SUMMARY OF THE INVENTION

An object of the present invention is to provide a substrate processing method for suppressing popping and increasing throughput.

One of inventive concepts disclosed in the present application can be explained in brief as follows.

There is provided a substrate processing method including: (a) loading into a process chamber a substrate having a photoresist film thereon with a dopant introduced therein; (b) heating the substrate to a first temperature; (c) supplying a first reaction gas containing oxygen and hydrogen components and a dilution gas into the process chamber in a manner that a flow rate of the hydrogen component ranges from 60% to 70% of a total flow rate of the first reaction gas; (d) processing the substrate with the first reaction gas in plasma state to remove at least a portion of the photoresist film (e) heating the substrate to a second temperature higher than the first temperature; (f) supplying a second reaction gas containing oxygen and hydrogen components and a dilution gas into the process chamber in a manner that a flow rate of the hydrogen component of the second reaction gas is higher than that of the hydrogen component of the first reaction gas; and (g) processing the substrate with the second reaction gas in plasma state to remove a remaining portion of the photoresist film.

### BRIEF DESCRIPTION OF THE DRAWINGS

FIG. 1 is a schematic cross-sectional view for illustrating an ashing apparatus according to a preferred embodiment of the present invention.

FIG. 2 is a schematic vertical sectional view for illustrating the ashing apparatus according to a preferred embodiment of the present invention.

FIG. 3 is a vertical sectional view for illustrating a plasma processing unit of the ashing apparatus according to a preferred embodiment of the present invention.

FIG. 4 is a perspective view for illustrating a susceptor table and lifter pins of the ashing apparatus according to a preferred embodiment of the present invention.

FIG. 5A to FIG. 5H are views for explaining a process of manufacturing a semiconductor device by using the ashing apparatus according to a preferred embodiment of the present invention.

FIG. 6 is a view for explaining processes of a substrate processing method using the ashing apparatus, according to an embodiment of the present invention.

FIG. 7 is a graph showing a relationship between the hydrogen concentration of reaction gas and the number of residue particles.

FIG. 8 is a graph showing emission intensities corresponding to concentrations of OH radicals, 0 radicals, and H radicals included in plasma with respect to the hydrogen/oxygen ratio of reaction gas composed of a (H₂+O₂) mixture.

FIG. 9 is a graph showing emission intensities corresponding to concentrations of OH radicals, O radicals, and H radicals included in plasma with respect to the hydrogen/oxygen ratio of reaction gas composed of a (H₂+H₂O) mixture.

FIG. 10 is a graph showing stripping residue reduction effects according to the H₂/O₂ ratio of reaction gas.

FIG. 11 is a graph showing stripping time and residue reduction effects according to substrate temperature.

### DETAILED DESCRIPTION OF THE PREFERRED EMBODIMENTS

Preferable embodiments of the present invention will be described hereinafter with reference to the attached drawings.

The present invention relates to a substrate processing method used for a semiconductor manufacturing apparatus, for example. Specifically, the present invention relates to a dry ashing process for stripping a predetermined organic thin film (photoresist or a photoresist film) from a surface of a substrate by using a reactive species (reactive activated species) which has high reactiveness and obtained by discharging reactive gas (into plasma state) with high-frequency waves.

In preferred embodiments of the present invention, by an ashing apparatus used as a semiconductor manufacturing apparatus, a semiconductor device manufacturing method and a substrate process method are implemented.

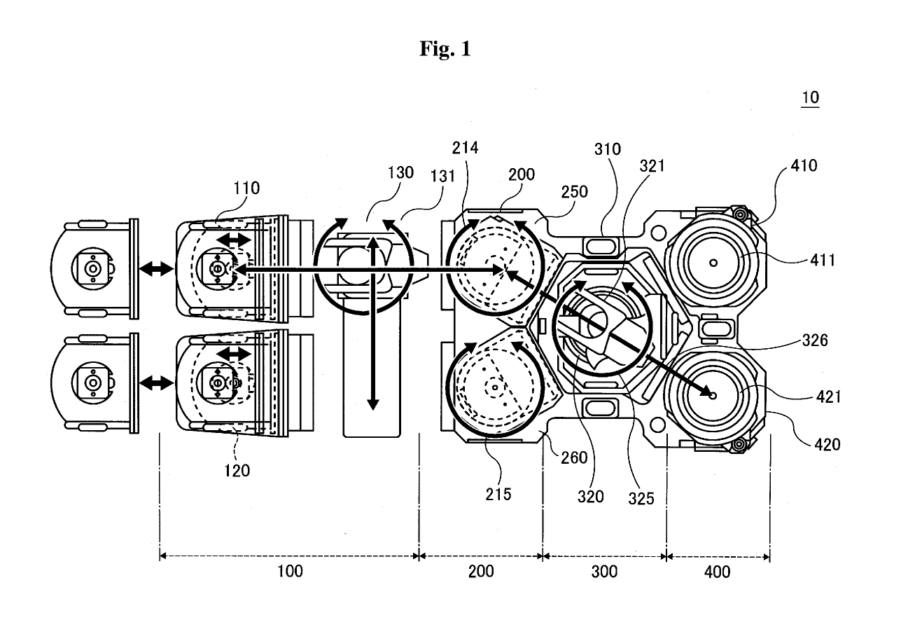

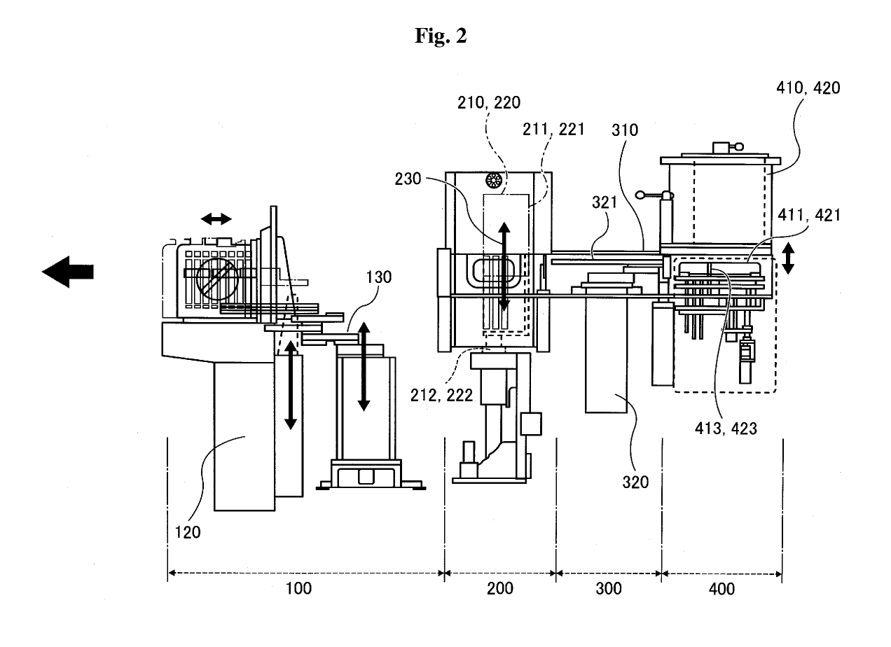

FIG. 1 is a schematic cross-sectional view for illustrating an ashing apparatus according to a preferred embodiment of the present invention, and FIG. 2 is a schematic vertical sectional view for illustrating the ashing apparatus according to a preferred embodiment of the present invention. As shown in FIG. 1 and FIG. 2, an ashing apparatus 10 includes an equipment front end module (EFEM) 100, a loadlock chamber part 200, a transfer module part 300, and a process chamber part 400 used as process chambers for performing ashing processes.

The EFEM 100 includes front opening unified pods (FOUPs) 110 and 120, and an atmospheric robot 130 configured to carry wafers from the FOUPs 110 and 120 to loadlock chambers.

Each FOUP can accommodate twenty five wafers, and an arm part of the atmospheric robot 130 can picks up five wafers from the FOUP at a time.

The loadlock chamber part 200 includes loadlock chambers 250 and 260, and buffer units 210 and 220 configured to hold wafers 600 carried from the FOUPs in the loadlock chambers 250 and 260. The buffer units 210 and 220 include boats 211 and 221, and index assemblies 212 and 222 under the boats 211 and 221. The boat 211 (221), and the index assembly 212 (222) are configured to be simultaneously rotated about a θ-axis 214 (224).

The transfer module part 300 includes a transfer module 310 as a carrying chamber, and the loadlock chambers 250 and 260 are attached to the transfer module 310 with gate values 311 and 312 being disposed therebetween. At the transfer module 310, a vacuum arm robot unit 320 is installed as a second carrying unit.

The process chamber part 400 includes plasma processing units 410 and 420 used as process chambers, and plasma generating chambers 430 and 440 above the plasma processing units 410 and 420. The plasma processing units 410 and 420 are attached to the transfer module 310 with gate valves 313 and 314 being disposed therebetween.

The plasma processing units 410 and 420 include susceptor tables 411 and 421 for placing wafers 600 thereon. Lifter pins 413 and 423 are installed through the susceptor tables 411 and 421, respectively. The lifter pins 413 and 423 move upward and downward in the directions of Z-axis 412 and 422.

The plasma generating chambers 430 and 440 include reaction vessels 431 and 441, respectively, and high-frequency coils 432 and 442 are installed outside the reaction vessels 431 and 441. High-frequency power is applied to the high-frequency coils 432 and 442 so that reaction gas introduced through gas introduction ports 433 and 443 for ashing is excited into plasma, and by using the plasma, an ashing process (plasma treatment) is performed on photoresist formed on wafers 600 placed on the susceptor tables 411 and 421.

In the ashing apparatus 10, wafers 600 are carried from the FOUPs 110 and 120 to the loadlock chamber 250 (260). For this, as shown in FIG. 2, the atmospheric robot 130 moves tweezers into a port of the FOUP so as to place five wafers on the tweezers. At this time, the tweezers and arm of the atmospheric robot 130 are lifted or lowered according to the heights of the wafers.

After the wafers are placed on the tweezers, the atmospheric (carrying) robot 130 rotates in the direction of a θ-axis 131 to load the wafers on the boat 211 (221) of the buffer unit 210 (220). At this time, the boat 211 (221) receives twenty five wafers 600 from the atmospheric carrying robot 130 while the boat 211 (221) moves in the direction of a z-axis 230. After twenty five wafers, the boat 211 (221) is operated in the direction of the z-axis 230 to align the lowermost wafer of the boat 211 (221) of the boat with the transfer module part 300.

In the loadlock chamber 250 (260), a wafer 600 held by the buffer unit 210 (220) disposed in the loadlock chamber 250 (260) is loaded on a finger 321 of the vacuum arm robot unit 320. The vacuum arm robot unit 320 is rotated in the direction of a θ-axis 325, and the finger is extended in the direction of a y-axis 326 so as to place the wafer 600 on the susceptor table 411 (421) of the plasma processing unit 410 (420).

Hereinafter, an explanation will be given on an operation of the ashing apparatus 10 for transferring a wafer 600 from the finger 321 to the susceptor table 411 (421).

By a cooperative operation of the finger 321 of the vacuum arm robot unit 320 and the lifter pin 413 (423), a wafer 600 is transferred onto the susceptor table 411 (421).

Furthermore, by a reverse operation, a processed wafer 600 is transferred from the susceptor table 411 (421) to the buffer unit 210 (220) inside the loadlock chamber 250 (260) by the vacuum arm robot unit 320.

In the above-described ashing apparatus 10, a wafer 600 is carried to the loadlock chamber 250 (260); the inside of the loadlock chamber 250 (260) is vacuum-evacuated (vacuum replacement); the wafer 600 is carried from the loadlock chamber 250 (260) to the plasma processing unit 410 (420) through the transfer module 310; photoresist is removed from the wafer 600 in the plasma processing unit 410 (420) (a removing process); and the wafer 600 from which photoresist is removed is carried back to the loadlock chamber 250 (260) via the transfer module 310.

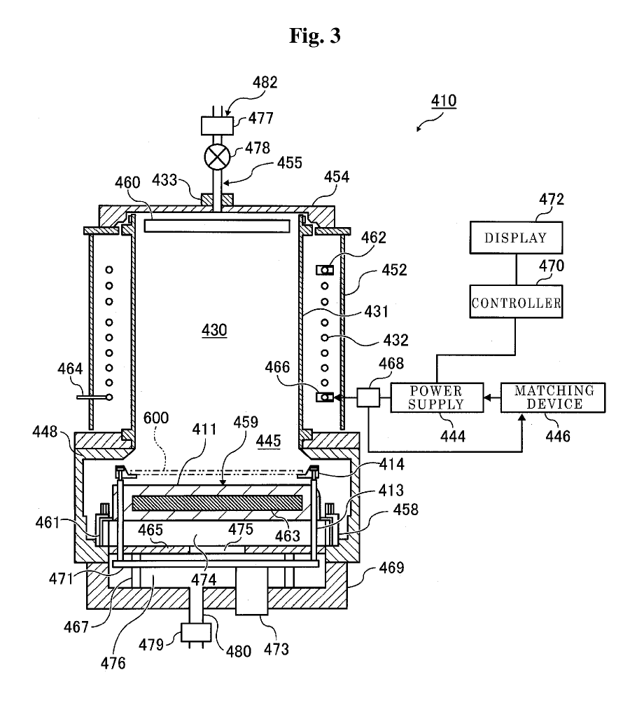

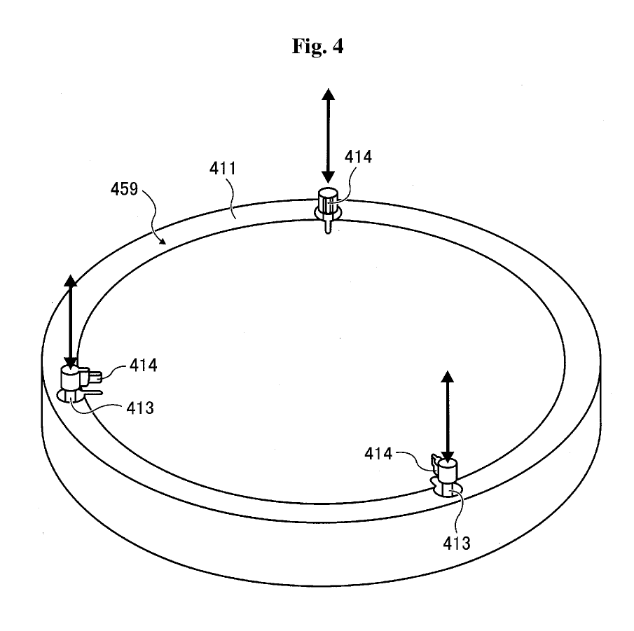

In FIG. 3, the plasma processing unit 410 is illustrated in detail, and in FIG. 4, the susceptor table 411 of the plasma processing unit 410 is illustrated in detail. In addition, the plasma processing unit 420 has the same structure as that of the plasma processing unit 410. Furthermore, the susceptor table 421 of the plasma processing unit 410 is the same as the susceptor table 411.

The plasma processing unit 410 is a high-frequency electrodeless discharge type process chamber configured to perform an ashing process on a semiconductor substrate or device as a dry treatment process. As shown in FIG. 3, the plasma processing unit 410 includes the plasma source 430 configured to generate plasma, a process chamber 445 configured to accommodate a semiconductor substrate such as a wafer 600, a high-frequency power supply 444 configured to supply high-frequency power to the plasma source 430 (particularly, to the resonance coil 432), and a frequency matching device 446 configured to control the oscillating frequency of the high-frequency power supply 444. For example, the plasma source 430 is located at the upper side of a horizontal base plate 448 used as a pedestal, and the process chamber 445 is located at the lower side of the base plate 448. In addition, the resonance coil 432 and an outer shield 452 constitute a spiral resonator.

The plasma source 430 is configured to be evacuated. The plasma source 430 includes the reaction vessel 431 to which a reaction gas is supplied for generating plasma, the resonance coil 432 which is wound around the reaction vessel 431, and the outer shield 452 which is disposed outside the resonance coil 432 and is electrically grounded.

The reaction vessel 431 is a chamber which is generally made of high-purity quartz glass or a ceramic material in a cylindrical shape. Generally, the centerline of the reaction vessel 431 is aligned in a vertical direction, and top and bottom sides of the reaction vessel 431 are air-tightly sealed by a top plate 454 and the process chamber 445. At the bottom side of the process chamber 445 located at the lower side of the reaction vessel 431, a susceptor 459 is installed, which is supported by a plurality of supports 461 (for example, four supports) and is provided with the susceptor table 411 and a substrate heating part 463 configured to heat a wafer disposed on the susceptor 459.

At the lower side of the susceptor 459, an exhaust plate 465 is installed. The exhaust plate 465 is supported by a lower base plate 469 with guide shafts 467 being disposed therebetween, and the lower base plate 469 is air-tightly installed to the bottom side of the process chamber 445. A lift base plate 471 is installed by using the guide shafts 467 as guides so as to be moved upward and downward. The lift base plate 471 includes at least three lifter pins 413.

As shown in FIG. 4, the lifter pins 413 are inserted through the susceptor table 411 of the susceptor 459. At the top sides of the lifter pins 413, supporting parts 414 are installed for supporting a wafer 600. The supporting parts 414 extend toward the center of the susceptor 459.

By moving the lifter pins 413 downward or upward, a wafer 600 can be placed onto the susceptor table 411 or lifted from the susceptor table 411.

A lift shaft 473 of a lift driving part (not shown) is connected to the lift base plate 471 through the lower base plate 469. The lift driving part moves the lift shaft 473 upward or downward so that the lifter pin supporting parts 414 connected to the lift shaft 473 through the lift base plate 471 and the lifter pins 413 can be moved upward and downward.

In addition, the lifter pins 413 on which the supporting parts 414 are installed are illustrated. Furthermore, in FIG. 4, arrows denote moving directions of the supporting parts 414.

Between the susceptor 459 and the exhaust plate 465, a baffle ring 458 is installed. A first exhaust chamber 474 is formed by the baffle ring 458, the susceptor 459, and the exhaust plate 465. In the baffle ring 458 having a cylindrical shape, a plurality of ventilation holes are uniformly formed. In this way, the first exhaust chamber 474 is separated from the process chamber 445 and communicates with the process chamber 445 through the ventilation holes.

In the exhaust plate 465, an exhaust hole 475 is formed. The first exhaust chamber communicates with a second exhaust chamber 476 through the exhaust hole 475. An exhaust pipe 480 communicates with the second exhaust chamber 476, and an exhaust device 479 is installed at the exhaust pipe 480.

At the top plate 454 of the reaction vessel 431, a gas supply pipe 455 which extends from a gas supply unit 482 is connected to the gas introduction port 433 for supplying reaction gas necessary for generating plasma. The gas supply unit 482 is configured to control the flowrate of gas. In detail, the gas supply unit 482 includes a mass flow controller 477 functioning as a flowrate control unit, and an on-off valve 478. The gas supply unit 482 adjusts the flowrate of gas by controlling the mass flow controller 477 and the on-off valve 478.

Furthermore, in the reaction vessel 431, a baffle plate 460 having an approximately disk shape and made of quartz is installed so that reaction gas can flow along the inner wall of the reaction vessel 431.

In addition, by controlling the supply amount of gas and the exhaust amount of gas by using the mass flow controller 477 and the exhaust device 479, the pressure of the process chamber 445 can be adjusted.

The winding diameter, winding pitch, and number of turns of the resonance coil 432 are adjusted to resonate the resonance coil 432 in constant wavelength mode so that standing waves having a predetermined wave length can be generated from the resonance coil 432. That is, the electric length of the resonance coil 432 is set to a length corresponds to a length that is an integer number (1, 2, . . . ) of times, ½, or ¼ the wavelength of power supplied from the high-frequency power supply 444. For example, if the frequency of power is 13.56 MHz, the wavelength of the power is about 22 meters; if the frequency is 27.12 MHz, the wavelength is about 11 meters; and if the frequency is 54.24 MHz, the wavelength is about 5.5 meters.

The resonance coil 432 is supported by a plurality of supports which are made of an insulating material in a flat plate shape and are perpendicularly erected on the top surface of the base plate 448.

Both ends of the resonance coil 432 are electrically grounded, and at least one end of the resonance coil 432 is electrically grounded via an adjustable tap 462 so that the electrical length of the resonance coil 432 can be finely adjusted when the ashing apparatus 10 is initially installed or process conditions are changed. In FIG. 3, reference numeral 464 denotes a fixed ground at the other side. Furthermore, a power feed part configured by an adjustable tap 466 is disposed between the grounded ends of the resonance coil 432 for finely adjusting the impedance of the resonance coil 432 when the ashing apparatus 10 is initially installed or process conditions are changed.

That is, the resonance coil 432 includes grounding parts at both ends for electric grounding, and the power feed part between the grounding parts for receiving power from the high-frequency power supply 444. In addition, at least one of the grounding parts of the resonance coil 432 is position-adjustable, and the power feed part of the resonance coil 432 is position-adjustable. Since the resonance coil 432 includes the variable grounding part and the variable power feed part, the resonance frequency and load impedance of the plasma source 430 can be adjusted more easily as described later.

The outer shield 452 is installed so as to prevent leakage of electromagnetic waves from the resonance coil 432 and form capacitance with the resonance coil 432 for constituting a resonant circuit. Generally, the outer shield 452 is made in a cylindrical shape using a conductive material, such as an aluminum alloy, copper, or a copper alloy. For example, the outer shield 452 is spaced about 5 mm to about 150 mm away from the outer circumference of the resonance coil 432.

A radio frequency (RF) sensor 468 is installed at the output side of the high-frequency power supply 444 so as to monitor traveling waves, reflected waves, etc. Reflected wave power detected by the RF sensor 468 is input to the frequency matching device 446. The frequency matching device 446 controls frequency to minimize reflected waves.

A controller 470 controls the entire operation of the ashing apparatus 10 as well as the operation of the high-frequency power supply 444. A display 472 is connected to the controller 470 as a display part. For example, the display 472 displays data detected by various detectors installed in the ashing apparatus 10 such as reflected wave monitoring results of the RF sensor 468.

For example, in an ashing process or a plasma generating process before the ashing process, plasma processing conditions may be changed (for example, the kinds of gases are increased), and in this case, gas flowrate, gas mixing ratio, or pressure may be changed. As a result, the load impedance of the high-frequency power supply 444 may be changed. However, since the ashing apparatus 10 includes the frequency matching device 446, the output frequency of the high-frequency power supply 444 can be matched according to variations of gas flowrate, gas mixing ratio, or pressure.

Specifically, the following operations are performed.

When generating plasma, the resonance coil 432 resonates. At this time, the resonance coil 432 monitors waves reflected from the resonance coil 432 and transmits the level of the reflected waves to the frequency matching device 446. The output frequency of the high-frequency power supply 444 is adjusted by using the frequency matching device 446 so as to minimize the power of the reflected waves.

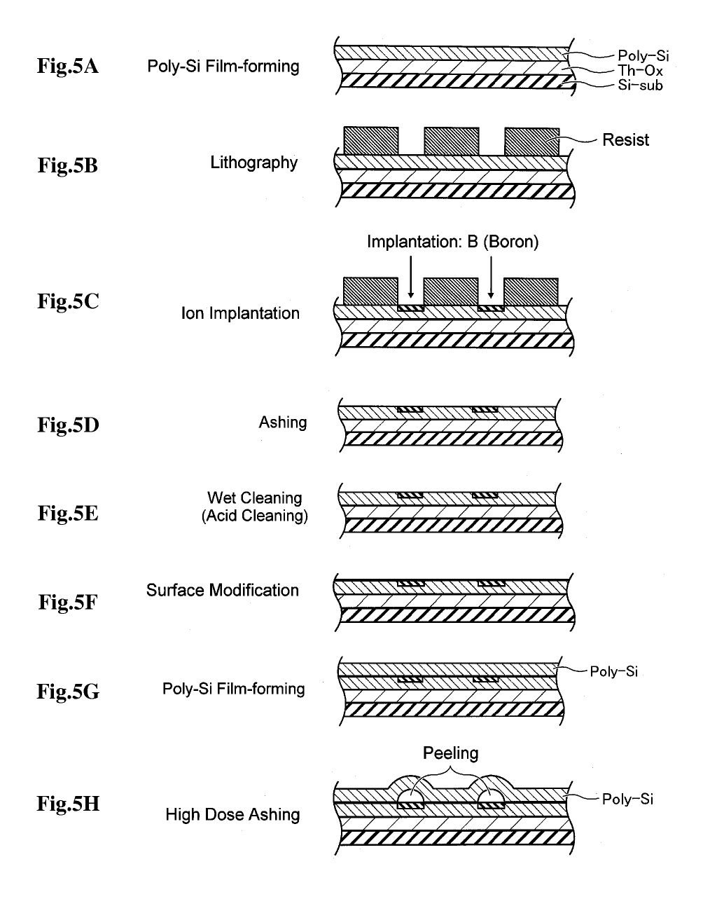

Next, a semiconductor manufacturing method using the substrate processing method (photoresist removing method) of the present invention will be explained with reference to FIG. 5. With reference to FIG. 5, explanations are given on processes for manufacturing a semiconductor device by using the substrate processing method of the present invention and other apparatuses such as the ashing apparatus 10.

As shown in FIG. 5A, in the substrate processing method, first, a Th—Ox layer and a Poly-Si layer are deposited on a Si-sub (substrate) in a Poly-Si film-forming process.

Next, as shown in FIG. 5B, in a lithography process, photoresist is applied to the substrate, and an exposing treatment is performed so as to form electrode grooves in the photoresist. After that, an etching process is performed.

Next, as shown in FIG. 5C, in an ion (impurity) implanting process, ions such as boron ions are implanted (ion implantation). At this time, the ions are implanted into the photoresist as wall as sources and drains.

Next, as shown in FIG. 5D, in an ashing process, the photoresist doped with ions is removed by ashing. In the ashing process, the above-described ashing apparatus 10 is used. The ashing process will be described later in more detail.

Next, as shown in FIG. 5E, in a wet cleaning process (acid cleaning process), the substrate is acid-cleaned and is wet-cleaned so as to remove particles from the substrate.

Next, as shown in FIG. 5F, in a surface modification process, an oxygen component is removed by leaking.

Next, as shown in FIG. 5G, in a Poly-Si film-forming process, a Poly-Si film is formed on the substrate. Thereafter, like the lithography process of FIG. 5B, photoresist is applied on the Poly-Si film, and the photoresist is etched to form a pattern. In this way, impurities are implanted into the Poly-Si film to form a doped Poly-Si (DOPOS, heavily doped poly silicon) film.

Thereafter, as shown in FIG. 5H, in a high dose ashing process, an ashing treatment is performed to remove the ion-doped photoresist from the DOPOS film. At this time, if the present invention is not applied, as shown in FIG. 5H, there may be peeling between the Poly-Si film formed in the Poly-Si film-forming process of FIG. 5G and the Poly-Si film formed in the Poly-Si film-forming process of FIG. 5A.

An ashing method for preventing such a peeling problem will be described later.

Next, according to the present invention, an exemplary process (Embodiment 1) performed by using the ashing apparatus 10 will be described.

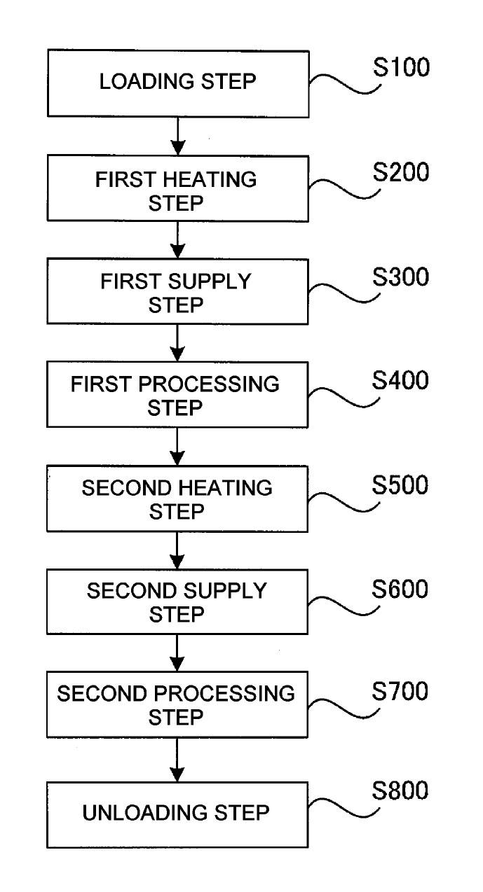

FIG. 6 illustrates a substrate processing method for a process of processing a substrate (wafer 600) using the ashing apparatus 10, according to an embodiment of the present invention.

In the substrate processing method of the present invention, as shown in FIG. 6, a substrate is processed through sequential processes including at least a loading step S100 for loading a substrate into a process chamber, a first heating step S200 for heating the substrate, a first supply step S300 for supplying reaction gas, a first processing step S400 for processing the substrate, and an unloading step S800 for unloading the substrate from the process chamber.

In the loading step S100, a wafer 600 coated with photoresist into which a dopant is permeated is loaded into the process chamber 445. In the first heating step S200, the wafer 600 loaded into the process chamber 445 in the loading step S100 is heated. In the first supply step S300, reaction gas is supplied to the process chamber 445. The reaction gas includes at least an oxygen component and a hydrogen component, and the concentration of the hydrogen component is 60% to 70%. In the first processing step S400, the wafer 600 is processed in a state where the reaction gas supplied to the process chamber 445 is excited into plasma. In the unloading step S800, the processed wafer 600 is unloaded from the process chamber 445.

Furthermore, as shown in FIG. 6, in Embodiment 1, in addition to the loading step S100, the first heating step S200, the first supply step S300, the first processing step S400, and the unloading step S800, a second heating step S500, and a second supply step S600, a second processing step S700 are sequentially performed to process a substrate.

In the second heating step S500, for example, the wafer 600 is heated at a temperature higher than that in the first heating step S200. In the second supply step S600, for example, reaction gas which includes at least a hydrogen component and an oxygen component is supplied to the process chamber 445. The concentration of the hydrogen component is lower than the concentration of the hydrogen component of the reaction gas used in the first supply step. In the second processing step S700, the wafer 600 is processed in a state where the reaction gas supplied to the process chamber 445 in S600 is excited in plasma.

Hereinafter, a detailed explanation will be given on the exemplary substrate processing process (Embodiment 1) using the ashing apparatus 10.

In addition, each part of the ashing apparatus 10 is controlled by the controller 470.

<Loading Step S100>

In the loading step S100, a wafer 600 is carried to the process chamber 445 by the finger 321 of the vacuum arm robot unit 320. That is, the finger 321 on which the wafer 600 is loaded is moved into the gas supply pipe 455, and the wafer 600 is placed on the lifted lifter pins 413 from the finger 321. The leading ends of the lifter pins 413 are kept above the susceptor table 411. The wafer 600 is placed on the lifter pins 413, that is, in a state where the wafer 600 is positioned above the susceptor table 411. At this time, the wafer 600 is kept, for example, at room temperature.

[First Heating Step S200]

In the first heating step S200, the wafer 600 is heated by the heater 463 of the susceptor table 411 in a state where the wafer 600 is kept above the susceptor table 411. The temperature of the wafer 600 is controlled by the distance between the susceptor table 411 and the wafer 600. In addition, the wafer 600 is gradually heated by plasma-state reaction gas in addition to heat from the susceptor table 411. At this time, the wafer 600 is heated to a temperature in a manner such that bubbles may not formed from gas included in a bulk layer of the wafer 600 or existing bubbles may not be enlarged.

In the first heating step S200, the wafer 600 may be heated to a temperature in the range from 220° C. to 300° C., preferably, 250° C. to 300° C.

[First Supply Step S300]

In the first supply step S300, reaction gas (ashing gas) is supplied to the plasma source 430 through the gas introduction port 433 of the reaction vessel 431. The reaction gas includes at least an oxygen gas component and a hydrogen component, and the concentration of the hydrogen component ranges from 60% to 70%. Here, the requirement that the concentration of the hydrogen component be 60% to 70% means that the supply flowrate of hydrogen gas is 60% to 70% of the total flowrate of the reaction gas. In other words, the ratio of hydrogen component/oxygen component is 160% to 400%.

[First Processing Step S400]

In the first processing step S400, the reaction gas supplied in the first supply step S300 is excited into plasma by the resonance coil 432 after the process chamber 445 is kept under predetermined conditions. That is, after the reaction gas is supplied in the reaction gas supply process, power is supplied to the resonance coil 432 to accelerate free electrons by using a magnetic field induced inside the resonance coil 432 and make the free electrons collide with gas molecules for exciting the molecules of the reaction gas into plasma. By using the plasma-state reaction gas, substrate processing is performed, and a hardened layer of photoresist is removed.

That is, the first processing step S400 is performed to remove photoresist, which is used as a mask in a previous substrate processing process of implanting ions into the wafer 600 (refer to FIG. 5C). Here, photoresist removed in the removing process includes a modified layer and a bulk layer, and at a high temperature (although variable according to a material of the photoresist, in the range from 120° C. to 160° C.), the modified layer may be broken by a pressure generated due to evaporation of the bulk layer (popping phenomenon).

In the first processing step S400 of Embodiment 1, gas including at least an oxygen component and a hydrogen component is used as reaction gas. For example, reaction gas may be a mixture of O₂ gas and H₂ gas, a mixture of H₂O gas and O₂ gas, or a mixture of NH₃ gas and O₂ gas which is diluted with at least one dilution gas selected from the group consisting of N₂ gas, He gas, Ne gas, Ar gas, Kr gas, and Xe gas.

In addition, reaction gas may be a mixture of H₂ gas, H₂O gas, NH₃ gas, and O₂ gas which is diluted with at least one selected from the group consisting of N₂ gas, He gas, Ne gas, Ar gas, Kr gas, and Xe gas.

O₂ gas is mainly used to remove photoresist, and H₂ gas is used to prevent popping. That is, by an activated species (mainly, O radicals) obtained by discharging reaction gas with high-frequency waves, organic components of photoresist becomes volatile components such as CO and CO₂ and are exhausted as gas.

In the first processing step S400 of Embodiment 1, as described above, so as to facilitate stripping of a hardened layer, the H₂ concentration (the concentration of H₂ component) of reaction gas is set in the range from 60% to 70%, which is higher than the H₂ concentration of reaction gas in a conventional process. In addition, for example, in the first heating step S200, since overheating of the wafer 600 facilitates stripping of a poly silicon film in which impurities are diffused, the lifter pins 413 are extended from the susceptor table 411 to prevent contact between the wafer 600 and the susceptor table 411, and discharging time is set to 30 seconds, so as to strip off photoresist while preventing stripping of the poly silicon film.

As described above, in the first processing step S400, the organic components of the photoresist are removed; however, dopants of the photoresist such as phosphorus (P), arsenic (As), and boron (B) are not removed although the dopants combine with O₂ because the dopants are not vaporized due to high bonding strength between the dopants and O₂. That is, in the first removing process, dopants implanted in the photoresist and oxides of the dopants may not be removed from the wafer 600 but they may be undesirably extracted to the surface of the wafer 600.

[Second Heating Step S500]

In the second heating step S500, the lifter pins 413 are lowered to place the wafer 600 on the susceptor table 411. After the wafer 600 is placed on the susceptor table 411, the influence of the heater 463 on the wafer 600 is increased, and as a result, the wafer 600 can be heated to a higher temperature than in first heating step S200.

[Second Supply Step S600]

The oxygen concentration of reaction gas supplied in the second supply step S600 is higher than that of reaction gas supplied in the first supply step S300. For example, the oxygen concentration of the reaction gas may be 90%. Owing to the high oxygen concentration, a layer of the photoresist located below the hardened layer of the photoresist which is removed in the first processing step S400 can be rapidly removed.

In addition, although gas including an oxygen component and a hydrogen component is supplied as reaction gas in the first supply step S300, for example, H₂N₂ gas to which nitrogen is added is supplied as reaction gas in the second supply step S600. In addition, the hydrogen concentration of the reaction gas is lower than the hydrogen concentration of reaction gas in the first processing step S400. Owing to this, a bulk photoresist layer can be rapidly stripped off, and overheating of the wafer 600 can be prevented to suppress stripping of the poly silicon film.

[Second Processing Step S700]

In the second processing step S700, the reaction gas supplied in the second supply step S300 is excited into plasma by the resonance coil 432. Then, by using the plasma-state reaction gas, substrate processing is performed, and a hardened layer of the photoresist is removed. More specifically, in the second processing step S700, impurities extracted to the surface of the wafer 600 are removed by using the reducing property of hydrogen (H), and H₂ gas is used to remove residues and N₂ gas is used as dilution gas.

[Unloading Step S800]

In the unloading step S800, after the ashing process, the lifter pins 413 are lifted. The finger 321 of the vacuum arm robot unit 320 picks up the processed wafer 600 from the lifter pins 413 and carries the processed wafer 600 to the loadlock chamber 210 or the loadlock chamber 220 via the transfer module 310.

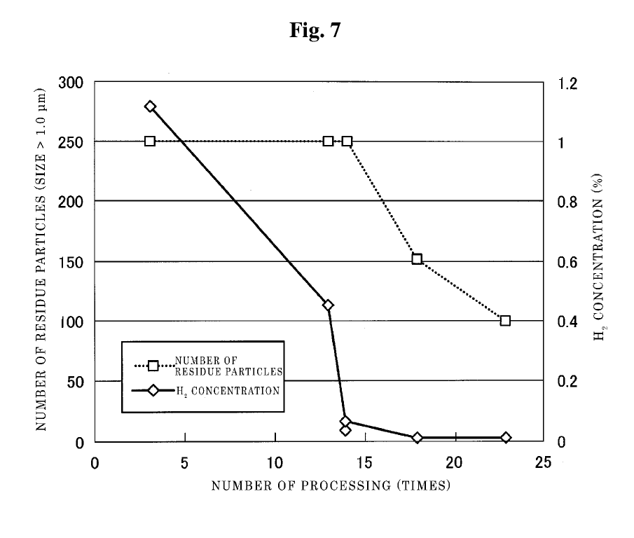

FIG. 7 is a graph showing a relationship between the hydrogen concentration of gas and the number of residue particles.

After a predetermined time from the start of a substrate processing process, the hydrogen concentration is kept at a second concentration which is equal to or lower than 1%. By keeping the hydrogen concentration equal to or lower than 1%, as shown in FIG. 7, the residue particle number can be largely reduced. In addition, it is preferable that the hydrogen concentration be adjusted to the second concentration before gas contained in a bulk layer expands to cause a popping phenomenon. In addition, it is preferable that the hydrogen concentration be adjusted to the second concentration after a hardened layer is removed.

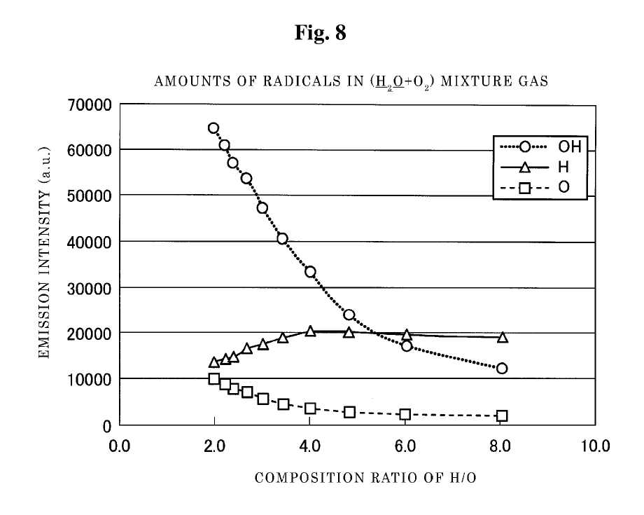

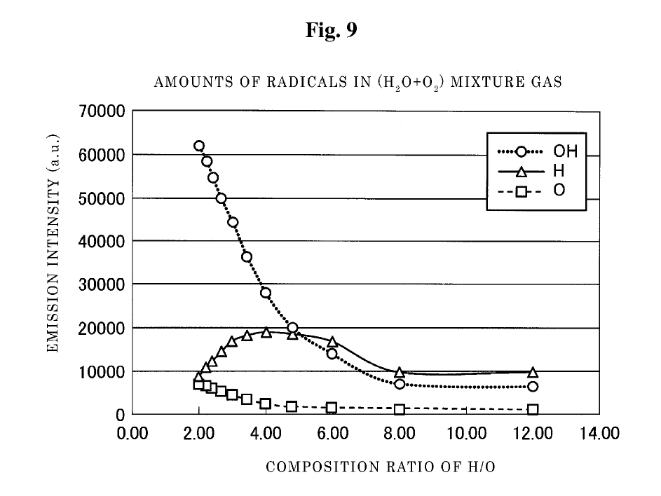

Next, with reference to FIG. 8 and FIG. 9, an explanation will be given on amounts of radicals generated, for example, in the first processing step S400.

FIG. 8 shows the amounts of OH, H, and O radicals in (H₂+O₂) mixture gas plasma. The vertical axis denotes emission intensity proportional to the amounts of radicals. The horizontal axis denotes the amount of hydrogen (H) element per oxygen (O) element (hydrogen/oxygen (H/O) ratio), and a high H/O ratio means a high amount of H₂ in the (H₂+O₂) mixture gas.

In plasma generated from reaction gas including oxygen and hydrogen, as shown in FIG. 9, an activated species mainly composed of OH radicals that can be obtained by electric discharge is included. Organic components and impurities included in a hardened layer are efficiently removed through reduction reactions with the OH radicals. If the amount of hydrogen is lower than 3 when the amount of oxygen is 1, that is, the H/O ratio is lower than 3, the amount of oxygen (O) radicals of the plasma increases as shown in FIG. 9. If the amount of oxygen (O) radicals increases, dopants of the hardened layer become a nonvolatile oxide by an oxidation reaction, and thus the hardened layer may not be easily removed. Therefore, a popping phenomenon may occur easily, and the dopant oxide may be extracted to form hard residues, which decreases stripping efficiency in an ashing process. Thus, it is preferable that the amount of hydrogen be kept equal to or higher than 3 when the amount of oxygen is 1.

FIG. 9 shows the amounts of radicals in the case where a mixture of H₂O gas and O₂ gas is used.

Like FIG. 8, the vertical axis of FIG. 9 denotes emission intensity, and the horizontal axis of FIG. 9 denotes the composition ratio of hydrogen/oxygen. Like in the case of using (H₂+O₂) mixture gas, when the composition ratio is lower than 3, the amount of OH radicals increases; however, the amount of oxygen (O) radicals also increases. In this case, dopants of a hardened layer may become a nonvolatile oxide by an oxidation reaction, and thus the hardened layer may not be easily removed. Therefore, when the (H₂O+O₂) mixture gas is used, it is also preferable that it is preferable that the amount of hydrogen be kept equal to or higher than 3 when the amount of oxygen is 1.

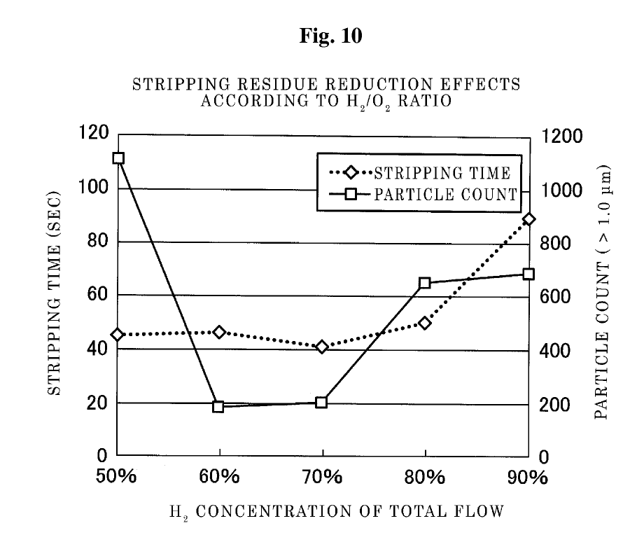

FIG. 10 is a graph showing stripping residue reduction effects according to the H₂ concentration of reaction gas composed of a mixture of O₂ gas and H₂ gas, in which relationships among the H₂ concentration of total gas flow, stripping time (sec), and the number of 1-μm or larger particles are shown. As shown in FIG. 10, by keeping the hydrogen (H₂) concentration of total gas flow in the range from 60% to 70%, the number of 1-μm or larger particles can be reduced, that is, the amounts of residues can be reduced.

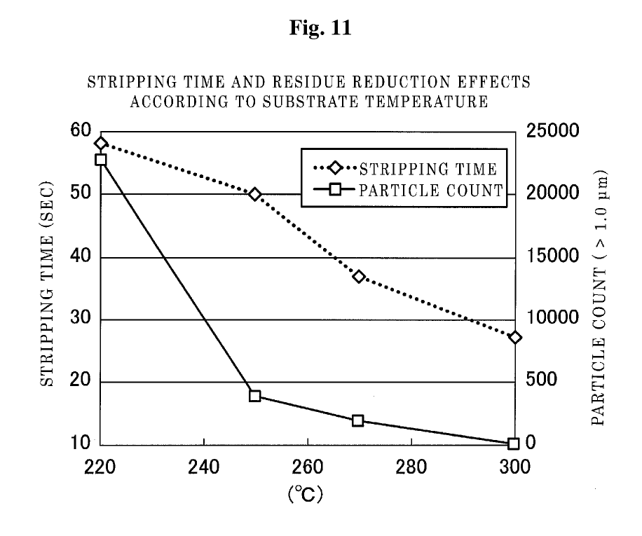

FIG. 11 is a graph showing stripping time and residue reduction effects according to substrate temperature, in which the relationships among substrate temperature, stripping time (sec), the number of 1-μm or larger particles are shown. As shown in FIG. 12, by keeping the temperature of s substrate at 250° C. or higher, the number of 1-μm or larger particles can be reduced, that is, the amounts of residues can be reduced. Furthermore, as it can be predicted from FIG. 12, if the temperature of the substrate is further increased to 300° C. or higher, the amounts of residues can be further reduced.

However, if the temperature of the substrate is kept at a high temperature, a popping phenomenon occurs easily. Moreover, when a popping phenomenon occurs, the scattering range of components is increased in proportion to the temperature of the substrate. Therefore, it is preferable that the temperature of a substrate be kept not higher than a predetermined temperature so as to prevent excessive generation of popping phenomenon.

Accordingly, it is preferable that the temperature of a substrate be kept in the range from 250° C. to 300° C., more preferably, 250° C. to 300° C., so as to reduce the amounts of residues while suppressing the popping phenomenon.

According to the substrate processing method of the present invention, in a photoresist removing process, popping can be suppressed while increasing the throughput.

As described above, the present invention can be applied to substrate processing methods, substrate processing apparatuses, semiconductor device manufacturing methods, and highly ion-implanted photoresist stripping methods.

Although the present invention is characterized by the appended claims, the present invention also includes the following embodiments.

[Supplementary Note 1]

According to an embodiment of the present invention, there is provided a substrate processing method comprising:

loading a substrate, which is coated with photoresist into which a dopant is introduced, into a process chamber;

heating the substrate;

supplying a reaction gas to the process chamber, wherein the reaction gas contains at least oxygen and hydrogen components, and concentration of the hydrogen component ranges from 60% to 70%; and

processing the substrate in a state where the reaction gas is excited into plasma.

[Supplementary Note 2]

In the substrate processing method of Supplementary Note 1, the substrate may be heated to 220° C. to 300° C. in the heating of the substrate.

[Supplementary Note 3]

In the substrate processing method of Supplementary Note 1, the substrate may be heated to 250° C. to 300° C. in the heating of the substrate.

[Supplementary Note 4]

According to another embodiment of the present invention, there is provided a substrate processing method comprising:

loading a substrate, which is coated with photoresist into which a dopant is introduced, into a process chamber;

supplying a reaction gas to the process chamber, wherein the reaction gas contains at least oxygen and hydrogen components, and concentration of the hydrogen component ranges from 60% to 70%;

heating the substrate to a first temperature; and

heating the substrate to a second temperature higher than the first temperature.

[Supplementary Note 5]

According to another embodiment of the present invention, there is provided a substrate processing method comprising:

loading a substrate, which is coated with photoresist into which a dopant is introduced, into a process chamber;

heating the substrate;

supplying a reaction gas to the process chamber, wherein the reaction gas contains at least oxygen and hydrogen components and has a first hydrogen concentration value; and

supplying a reaction gas to the process chamber, wherein the reaction gas contains at least oxygen and hydrogen components and has a second hydrogen concentration value smaller than the first hydrogen concentration value;

processing the substrate in a state where the reaction gas having the first hydrogen concentration value and the reaction gas having the second hydrogen concentration value are excited into plasma.

[Supplementary Note 6]

According to another embodiment of the present invention, there is provided a substrate processing apparatus:

a substrate placement unit installed in a process chamber so as to receive a substrate coated with photoresist into which a dopant is introduced and heat the substrate;

a supply unit configured to supply a reaction gas to the process chamber;

a plasma generating unit configured to excite the reaction gas supplied to the process chamber into plasma; and

a control unit configured to control the substrate placement unit to heat the substrate, the supply unit to supply a reaction gas containing at least an oxygen component and 60% to 70% of hydrogen component to the process chamber, and the plasma generating unit to excite the reaction gas supplied to the process chamber.

[Supplementary Note 7]

According to another embodiment of the present invention, there is provided a semiconductor manufacturing method comprising:

supplying a reaction gas containing at least oxygen and hydrogen components; and

processing a semiconductor substrate disposed in a process chamber by using an reactive activated species obtained by discharging the reaction gas with high-frequency power,

wherein the processing of the semiconductor substrate comprises:

performing a first substrate processing process by electrically discharging a reaction gas having a first hydrogen concentration; and

after a predetermined time, performing a second substrate processing process by electrically discharging a reaction gas having a second hydrogen concentration higher than the first hydrogen concentration.

[Supplementary Note 8]

In the semiconductor manufacturing method of Supplementary Note 7, the first substrate processing process may be performed at a first substrate temperature, and the second substrate processing process may be performed at a second substrate temperature higher than the first substrate temperature.

[Supplementary Note 9]

In the semiconductor manufacturing method of Supplementary Note 7 or 8, the first hydrogen concentration may be equal to or higher than 30% but lower than 100%.

[Supplementary Note 10]

In the semiconductor manufacturing method of one of Supplementary Notes 7 to 9, the reaction gas may be excited into plasma in the first substrate processing process, and a plasma discharging time in the first substrate processing process may be 20 seconds to 30 seconds.

[Supplementary Note 11]

In the semiconductor manufacturing method of one of Supplementary Notes 7 to 10, the second hydrogen concentration may be 1% or lower.

[Supplementary Note 12]

In the semiconductor manufacturing method of one of Supplementary Notes 7 to 11, the reaction gas may contain inert gas as well as the oxygen and hydrogen components.

[Supplementary Note 13]

According to another embodiment of the present invention, there is provided a substrate processing method comprising:

performing a first removing process in a process chamber so as to remove photoresist coated on a substrate by using a reaction gas containing at least oxygen component and 60% to 70% of hydrogen component; and

performing a second removing process in the process chamber so as to further remove photoresist from the substrate by using a reaction gas having a hydrogen concentration smaller than the hydrogen concentration of the reaction gas used in the first removing process.

[Supplementary Note 14]

According to another embodiment of the present invention, there is provided a method of stripping heavily ion implanted photoresist, the method comprising:

supplying a reaction gas to an airtight discharge chamber; and

processing a semiconductor substrate disposed in a process chamber by using an reaction activated species obtained by discharging the reaction gas supplied to the discharge chamber with high-frequency power,

wherein the reaction chamber is kept in a temperature range from 220° C. to 300° C. during the processing of the semiconductor substrate, and the reaction gas contains at least oxygen and hydrogen components at a hydrogen/oxygen ratio ranging from 2 to 12.

[Supplementary Note 15]

In Supplementary Notes 1, 4, 5, 7, 13, and 14, it is preferable that the reaction gas be a mixture prepared by mixing H₂ gas, H₂O gas, NH₃ gas, and O₂ gas with at least one selected from the group consisting of N₂ gas, He gas, Ne gas, Ar gas, Kr gas, and Xe gas.

[Supplementary Note 16]

In Supplementary Notes 1, 4, 5, 7, 13, and 14, it is preferable that the reaction gas be a mixture of H₂ gas and O₂ gas.

[Supplementary Note 17]

In Supplementary Notes 1, 4, 5, 7, 13, and 14, it is preferable that the reaction gas be a mixture of H₂O gas and O₂ gas.

[Supplementary Note 18]

In Supplementary Notes 1, 4, 5, 7, 13, and 14, it is preferable that the reaction gas be a mixture of NH₃ gas and O₂ gas.

[Supplementary Note 19]

In Supplementary Notes 1, 4, 5, 7, 13, and 14, it is preferable that the reaction gas be prepared by adding at least one dilution gas selected from the group consisting of N₂ gas, He gas, Ne gas, Ar gas, Kr gas, and Xe gas to the mixture gas of any one of Supplementary Notes 14 to 17.

[Supplementary Note 20]

In Supplementary Notes 1, 4, 5, 7, 13, and 14, if a plurality of processes are performed by using different reaction gases, at least one of the plurality of processes is performed by using the reaction gas of any one of Supplementary Notes 14 to 18.

What is claimed is:

1. A substrate processing method comprising:
(a) loading into a process chamber a substrate having a photoresist film thereon with a dopant introduced therein;
(b) heating the substrate to a first temperature;
(c) supplying a first reaction gas containing oxygen and hydrogen components and a dilution gas into the process chamber in a manner that a flow rate of the hydrogen component ranges from 60% to 70% of a total flow rate of the first reaction gas;
(d) processing the substrate with the first reaction gas in plasma state to remove at least a portion of the photoresist film;
(e) heating the substrate to a second temperature higher than the first temperature;
(f) supplying a second reaction gas containing oxygen and hydrogen components and a dilution gas into the process chamber in a manner that a flow rate of the hydrogen component of the second reaction gas is higher than that of the hydrogen component of the first reaction gas; and
(g) processing the substrate with the second reaction gas in plasma state to remove a remaining portion of the photoresist film.
